(19) United States
(12) Patent Application Publication
(10) Pub. No.: US 2006/0208325 A1
(43) Pub. Date: Sep. 21, 2006

(54) Semiconductor device with gate insulating film and manufacturing method thereof

(75) Inventors: Masaharu Mizutani, Tokyo (JP); Masao Inoue, Tokyo (JP); Jiro Yugami, Tokyo (JP); Junichi Tsuchimoto, Tokyo (JP); Koji Nomura, Itami-shi (JP); Yasuhiro Shimamoto, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/373,112

(22) Filed: Mar. 13, 2006

(30) Foreign Application Priority Data
Mar. 17, 2005 (JP) 2005-077498(P)
Feb. 16, 2006 (JP) 2006-038918(P)

(51) Int. Cl. H01L 29/94

(52) U.S. Cl. 257/411

(57) ABSTRACT

A MISFET includes: a p type substrate having a channel region with an impurity concentration C; an insulating film made of SiO₂ and formed on the channel region; and an insulating film made of HfSiON and formed on the gate insulating film. When there is a postulated MISFET including a postulated substrate having a channel region with the impurity concentration C and made of a material identical to the substrate and an insulating film made solely of SiON formed on the channel region, said impurity concentration C of channel region is set so that a maximum value of mobility of electrons in said channel region is higher than a maximum value of mobility of electrons in the postulated channel region. Thus, the power supply voltage can be reduced and the power consumption can be reduced.

### BACKGROUND OF THE INVENTION

1. Field of the Invention

The present invention relates to a semiconductor device and a manufacturing method thereof, and more specifically, to a semiconductor device with a gate insulating film made of a high-dielectric material and a manufacturing method thereof.

2. Description of the Background Art

Conventionally, MIS (metal-insulator semiconductor) FETs (field-effect transistors) as basic constituent circuitry for LSIs (large-scale integrated circuits) have been highly integrated in accordance with the scaling low. In a MISFET, a silicon dioxide (SiO₂) has been used as a gate oxide film. However, it is considered that the thickness of the gate insulating film of SiO₂ is limited to be about 2.0 nm. That is, if the gate insulating film of SiO₂ is thinner than about 2.0 nm, a problem arises that the power consumption increases due to an increase in a tunnel leakage current. Additionally, another problem arises that the reliability of the gate insulating film decreases. Further, still another problem arises that a diffusion barrier against impurities weakens and impurity leakage from a gate electrode is invited. Still further, a stringent production control is necessary for mass production of thin SiO₂ films at a good uniformity.

Accordingly, for attaining compatibility between further miniaturization and speed enhancement of the element and braking through the limit for the scaling, development for high-dielectric (high-K) materials capable of obtaining a field effect performance equal to or superior to SiO₂ even when they are formed thinner than SiO₂ has been conducted actively. Potential candidate materials include group IV oxides such as zirconia (ZrO₂), hafnia (HfO₂), group III oxides such as alumina (Al₂O₃), yttria (Y₂O₃), and silicate and the like. The group IV oxides and the group III oxides had been used as gate insulating films in early Si semiconductor devices. However, after the technique for forming a gate insulating film of SiO₂ was established, SiO₂ has been used exclusively in view of its excellent characteristics.

On the other hand, there are the following problems when manufacturing a MISFET applying a high-dielectric material such as Al₂O₃ to a gate insulating film. Since pinning occurs when a gate insulating film of a high-dielectric material and a polysilicon electrode are combined, a flat band voltage of an N channel MISFET shifts by about 0.3 V toward a positive voltage, and a threshold voltage of the MISFET also changes. Further, since the mobility of electrons is small, being about ¼ of the universal curve of an SiO₂ film, the source-drain current when the MISFET is operated cannot be increased as expected. One of the reasons that the mobility of electrons is small is attributable to scattering of electrons in the channel because of the presence of fixed charges in the insulating film.

Here, the universal curve is a general curve that provides effective field dependence of the mobility of carriers, which empirically defines the maximum value of the mobility of carriers in a MISFET having an insulating film of SiO₂. The universal curve is employed widely for comparing the mobility of carriers in a MISFET. S. Takagi et al., “On the Universality of Inversion Layer Mobility in Si MOSFET's: Part I—Effects of Substrate Impurity Concentration”, IEEE Trans. Electron Devices., Vol. 41 No. 12 pp. 2357-2362, 1994 describes a universal curve of a MISFET having a gate insulating film of SiO₂. The universal curve is shown in FIG. 16. FIG. 16 shows changes in the mobility of electrons relative to the effective field, wherein the surface orientation of the main surface of the silicon substrate is (100) and the temperature of the substrate is 77 K and 300 K. Referring to FIG. 16, the mobility of electrons at a certain substrate temperature and at a certain substrate concentration N_{A} has the maximum value at a certain effective field intensity.

As to the improvement of the mobility of electrons, Japanese Patent Laying-Open No. 2003-069011 discloses a semiconductor device wherein a gate insulating film of Al₂O₃ is formed on an Si (silicon) substrate, and a silicon oxide film or a silicon oxynitride film is formed in a region between the Si substrate and a metal oxide. Thus, formation of a metallic AlOX bonding state at Al₂O₃/Si interface is prevented, generation of electrons from the AlOX bonding state is prevented, and fixed charges at Al₂O₃/Si substrate interface can be reduced. As a result, the mobility of electrons in an N channel MISFET is improved to achieve about ¾ of the universal curve of an SiO₂ film.

When a high-dielectric material is used as a gate insulating film, the mobility of electrons in the channel region has been small. Accordingly, the current passing between source and drain decreases and the required on-current is not obtained, and therefore the power supply voltage must be increased. As a result, there has been a problem that the power consumption increases. Additionally, fast operation has not been realized. Even with the technique disclosed in Japanese Patent Laying-Open No. 2003-069011, the mobility of electrons has not exceeded the universal curve, being insufficient as the mobility of carriers.

### SUMMARY OF THE INVENTION

Accordingly, an object of the present invention is to provide a semiconductor device that can reduce power consumption and a manufacturing method thereof.

Another object of the present invention is to provide a semiconductor device that can realize fast operation and a manufacturing method thereof.

A semiconductor device of the present invention includes: a semiconductor substrate having a channel region with an impurity concentration C; a first gate insulating film containing silicon and oxygen and formed on the channel region; and a second gate insulating film containing hafnium and oxygen and formed on the first gate insulating film. When there is a postulated semiconductor device including a postulated semiconductor substrate that has a postulated channel region with the impurity concentration C and that is made of a material identical to the semiconductor substrate and a postulated gate insulating film made solely of SiON (silicon oxynitride) and formed on the postulated channel region, the impurity concentration C of the channel region is set so that a maximum value of mobility of electrons in the channel region is higher than a maximum value of mobility of electrons in the postulated channel region.

A manufacturing method of a semiconductor device according to the present invention includes the steps of: forming a channel region with an impurity concentration C in a semiconductor substrate; forming a first gate insulating film containing silicon and oxygen on the channel region; and forming a second gate insulating film containing hafnium and oxygen on the first gate insulating film. The impurity concentration C is set so that, in the step of forming a channel region, a maximum value of mobility of electrons in the channel region is higher than a maximum value of mobility of electrons in a channel region where only a gate insulating film made of silicon oxynitride is formed on the channel region with the impurity concentration C.

The inventors of the present invention found that, even when a high-dielectric material containing hafnium and oxygen was used as a gate insulating film, by setting an impurity concentration C of a channel region in a semiconductor substrate to an appropriate value, the mobility of electrons in the channel region could drastically be improved. That is, when there is a postulated semiconductor device including a postulated semiconductor substrate that has a postulated channel region with the impurity concentration C and that is made of a material identical to the semiconductor substrate and a postulated gate insulating film made solely of SiON and formed on the postulated channel region, according to the semiconductor device and its manufacturing method of the present invention, the impurity concentration C of the channel region is set so that a maximum value of mobility of electrons in the channel region is higher than a maximum value of mobility of electrons in the postulated channel region. Thus, the mobility of electrons can be improved.

Additionally, by forming the first gate insulating film, the second gate insulating film can be separated from the semiconductor substrate. Thus, the fixed charges in the second insulating film can be separated from the channel region. As a result, the mobility of electrons can be improved.

By improving the mobility of electrons, the power supply voltage can be reduced, since the current passing between source and drain increases. As a result, the power consumption can be reduced. Further, fast operation can be realized.

It is noted that, in the present specification, a “high field region” refers to a region where the field intensity is at least 0.8 (MV/cm) in a direction perpendicular to the surface of the semiconductor substrate in the channel region.

It is noted that EOT (Equivalent Oxide Thickness) refers to a physical thickness of a high-K film being converted to an electric thickness equivalent to an SiO2 film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing one example of the configuration of a semiconductor device of the present invention.

FIG. 2 is a schematic cross-sectional view of the configuration of a postulated semiconductor device in the present invention.

FIG. 3 shows the relationship between mobility and the physical film thickness of a gate insulating film in the present invention.

FIGS. 4-11 are enlarged cross-sectional views showing the sequence of manufacturing steps of a manufacturing method of a semiconductor device in a first embodiment of the present invention.

FIG. 12 is an enlarged cross-sectional view showing a manufacturing method of a semiconductor device in a second embodiment of the present invention.

FIG. 13 shows the mobility of electrons measured with specimens A1-A4 and the mobility of electrons measured with specimens C1-C4.

FIG. 14 shows the mobility of electrons measured with specimens B1-B4 and the mobility of electrons measured with specimens C1-C4.

FIG. 15 is a graph wherein maximum value μₘₐₓ of mobility μ of electrons measured with each specimen is plotted.

FIG. 16 shows a universal curve disclosed in S. Takagi et al., “On the Universality of Inversion Layer Mobility in Si MOSFET's: Part I—Effects of Substrate Impurity Concentration”, IEEE Trans. Electron Devices., Vol. 41 No. 12 pp. 2357-2362, 1994.

### DESCRIPTION OF THE PREFERRED EMBODIMENTS

In the following, embodiments of the present invention are described based on the drawings.

### First Embodiment

Referring to FIG. 1, a surface of a substrate 1 is electrically isolated by STI (Shallow Trench Isolations) 5a and 5b, and a MISFET 10 is formed on the surface of substrate 1 electrically isolated. MISFET 10 mainly includes substrate 1 as a semiconductor substrate, an insulating film 11 as a first gate insulating film, and an insulating film 12 as a second gate insulating film. Substrate 1 has a channel region 20 with an impurity concentration C in a prescribed region on the surface. On channel region 20, insulating film 11 is formed, and on insulating film 11, insulating film 12 is formed.

Substrate 1 is formed of silicon, for example, and attains p⁻ through an ion implantation of an impurity such as B (boron) into the substrate. In the present embodiment, impurity concentration C is set assuming a postulated semiconductor device having the following structure.

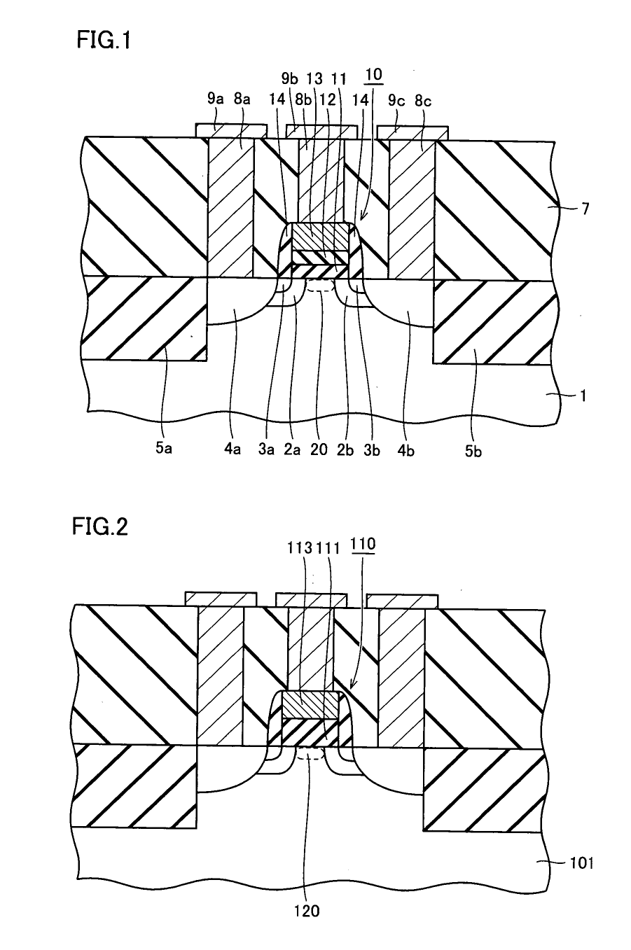

Referring to FIG. 2, a MISFET 110 as a postulated semiconductor device includes a substrate 101 as a postulated semiconductor substrate and an insulating film 111 as a postulated gate insulating film. Substrate 101 is a p type semiconductor substrate made of silicon, and insulating film 111 made of SiON is formed at a prescribed position on substrate 101, and a gate electrode 113 is formed on insulating film 111. Substrate 101 has a channel region 120 as a postulated channel region in a region vertically and immediately below insulating film 111.

Referring to FIGS. 1 and 2, in the present embodiment, the impurity concentration C of channel region 20 is set so that the maximum value of the mobility of electrons in channel region 20 of MISFET 10 is higher than the maximum value of the mobility of electrons in channel region 120 of MISFET 110. The impurity concentration C is, for example, at least 2×10⁷/cm³ and at most 1×10²⁰/cm³.

Referring to FIG. 1, while insulating film 11 is for example made of either SiON or SiO₂, it may be formed of other materials so long as it contains at least silicon and oxygen. SiON and SiO₂ are suitable as the material of insulating film 11 since they hardly react with insulating film 12 and have heat-resistance and high dielectric constant. EOT of insulating film 11 is for example at least 0.55 nm and at most 1.0 nm. By setting the thickness of insulating film 11 to at least 0.55 nm, insulating film 12 can fully be separated from substrate 1, whereby the mobility of electrons can be improved. By setting the thickness of insulating film 11 to at most 1.0 nm, the thickness level that can achieve the function of a gate insulating film can be ensured.

While insulating film 12 is for example made of HfSiON, it may be formed of other materials so long as it contains at least hafnium and oxygen. Since HfSiON has high dielectric constant and it hardly crystallizes, it is suitable as the material of insulating film 12.

MISFET 10 further includes a gate electrode 13 formed on insulating film 12. While gate electrode 13 is formed of for example polysilicon, it may be formed of other materials.

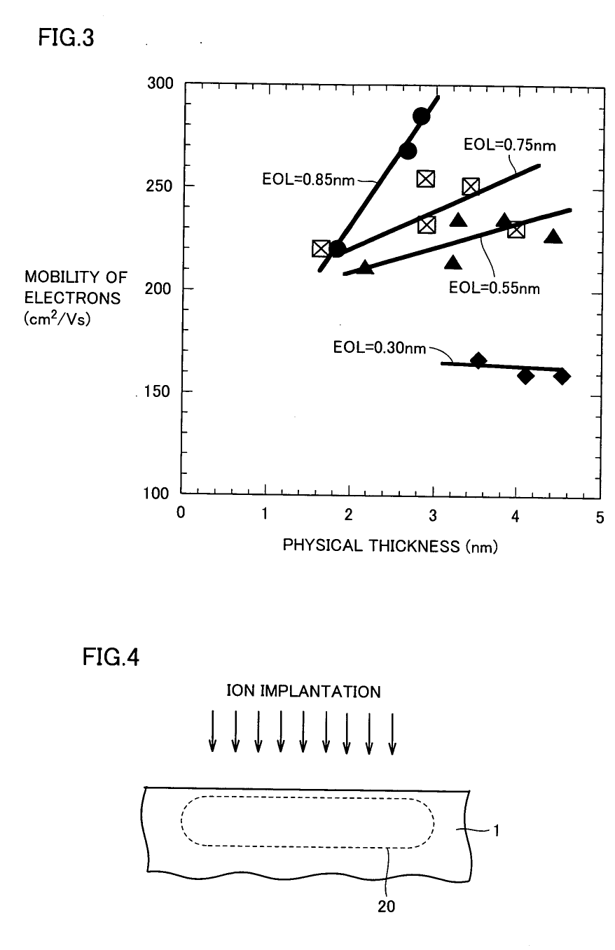

The present applicants have set EOT of insulating film 11 (interface layer) to 0.30 nm, 0.55 nm, 0.75 nm, and 0.85 nm with the semiconductor device shown in FIG. 1 to see the relationship between the physical thickness of insulating film 12 made of HFSiON and the mobility of electrons in each case. The effective field intensity E_{eff} was set to 0.8 MV/cm. The result is shown in FIG. 3. Referring to FIG. 3, as the physical thickness of insulating film 12 is thinner, the mobility of electrons is smaller. However, when EOT of insulating film 11 is at least 0.55 nm, higher mobility is maintained as compared with the case where EOT of insulating film 11 is less than 0.55 nm.

Referring to FIG. 1, description is given as to the configuration of a semiconductor device other than the one described above. Sidewalls 14 are formed on a substrate 1 so as to cover respective sides of an insulating film 11, an insulating film 12, and a gate electrode 13. On the surface of substrate 1, source and drain regions are formed with a channel region 20 interposed between them. The source region is constituted by an n⁺ type impurity region 4a and an n type impurity region 3a, while the drain region is constituted by an n⁺ type impurity region 4b and an n type impurity region 3b. At the boundaries between the source region and substrate 1 and between the drain region and substrate 1, p type impurity regions 2a and 2b are formed, respectively.

N type impurity region 3a is formed so as to be adjacent to n⁺ type impurity region 4a and to extend toward channel region 20. N type impurity region 3a is formed in a region that is inside p type impurity region 2a and that is vertically and immediately below sidewall 14. Similarly, n type impurity region 3b is formed so as to be adjacent to n⁺ type impurity region 4b and to extend toward channel region 20. N type impurity region 3b is formed in a region that is inside p type impurity region 2b and that is vertically and immediately below sidewall 14.

Here, by forming n type impurity regions 3a and 3b, which are the regions lower than n⁺ type impurity regions 4a and 4b in impurity concentration, the electric field around the interface between the drain region and the channel region can be relaxed, and the off current value can be reduced. Additionally, by forming p type impurity regions 2a and 2b at the boundaries between the source region and substrate 1 and between the drain region and substrate 1, punch through can be prevented.

An interlayer insulating film 7 is formed on the surface of substrate 1 so as to cover MISFET 10. Interlayer insulating film 7 is provided with a plurality of holes reaching the surface of substrate 1, and contacts 8a-8c are formed so that the holes are filled. Further, interconnection lines 9a-9c are formed on interlayer insulating film 7. Interconnection line 9a is electrically connected to n⁺ impurity region 4a via contact 8a. Interconnection line 9b is electrically connected to gate electrode 13 via contact 8b. Interconnection line 9c is electrically connected to n⁺ type impurity region 4b via contact 8c.

Next, referring to FIGS. 4-11, a manufacturing method of a semiconductor device in the present embodiment is described. FIGS. 4-7 are enlarged views around the channel region.

First, referring to FIG. 4, a substrate 1 made of monocrystalline silicon is prepared, and STIs 5a and 5b (FIG. 1) are formed on the surface of substrate 1. Next, for example with the condition of acceleration energy of 3 keV and dose of 1×10⁵/cm², ion implantation of B is performed from the direction perpendicular to the surface of substrate 1. Thus, p type channel region 20 having impurity concentration C of, for example, at least 2×10¹⁷/cm³ and at most 1×10²⁰/cm³ is formed.

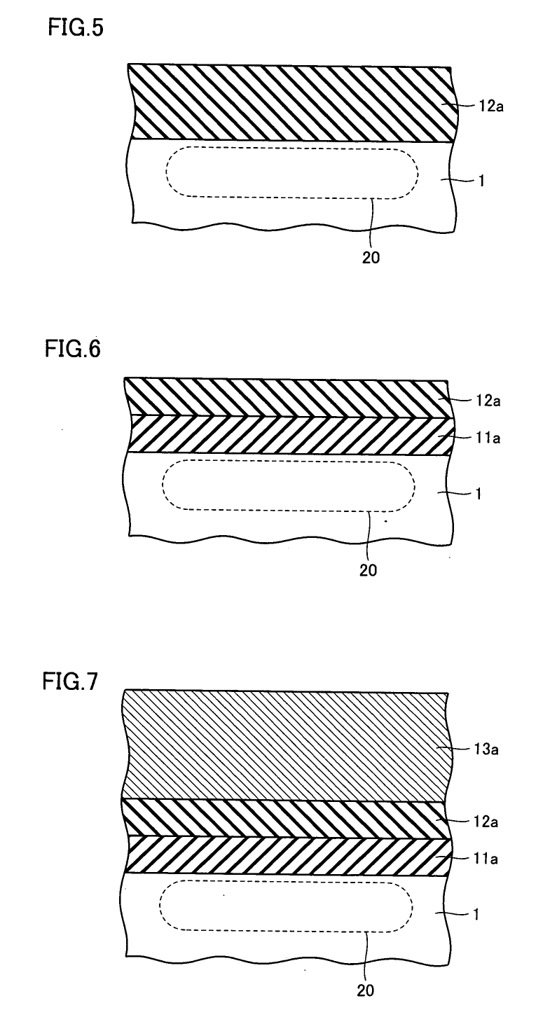

Next, referring to FIG. 5, through CVD (Chemical Vapor Deposition) method using for example HfCl₄ and SiH₄ as the material gas and H₂O as the oxidizing gas, an insulating film 12a made of HfSiO is formed on substrate 1 with a thickness of 0.7 nm. Insulating film 12a may be formed through a method other than CVD method, and it may be formed through sputtering method using an oxide target.

Next, referring to FIG. 6, heat treatment of substrate 1 is performed in an atmosphere of for example oxygen partial pressure of at least 25 Pa and at most 100 kPA at a temperature of at least 1000° C. and lower than 1100° C. for at least 20 seconds and at most 40 seconds. Thus, oxygen in the atmosphere passes through insulating film 12a to oxidize the surface of substrate 1, and insulating film 11a made of SiO₂ is formed on the surface of substrate 1. Additionally, by performing the heat treatment at a high temperature of at least 1000° C., Hf in insulating film 12a diffuses into insulating film 11a, whereby the mobility of electrons can be improved. Next, insulating film 12a is plasma-nitrided. Thus, insulating film 12a is nitrided and insulating film 12a made of HFSiON is formed. As above, by nitriding HfSiO to obtain HfSiON, insulating film 12 may hardly be crystallized. It is preferable to use plasma nitriding as the nitriding method of HfSiO. Employing plasma nitriding, the quantity of nitride to be introduced into the interface layer (insulating film 11) can be reduced to prevent a decrease in the mobility.

Next, referring to FIG. 7, a conductive film 13 made of for example TaN (tantalum nitride) is formed through reactive sputtering method. As conductive film 13a, instead of TaN, TiN (titanium nitride), WN (tungsten nitride), MoN (molybdenum nitride), ZrN (zirconium nitride), or HfN (hafnium nitride) may be used. Further, conductive film 13 a made of W (tungsten) may be formed using sputtering method or CVD method.

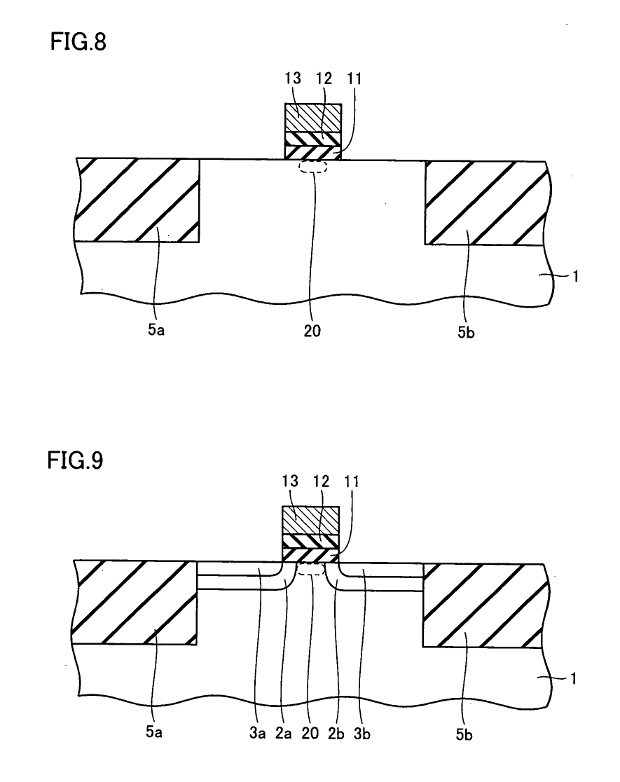

Next, referring to FIG. 8, a not-shown photoresist is formed, which is employed as a mask to etch insulating film 11a, insulating film 12a and conductive film 13a in prescribed shapes. Thus, insulating films 11 and 12 as gate insulating films and gate electrode 13 are formed. Thereafter, the photoresist is removed.

Next, referring to FIG. 9, for example with the condition of acceleration energy of 3 keV and dose of 1×10¹⁵/cm², ion implantation of As (arsenic) is performed from the direction perpendicular to the surface of substrate 1, to form n type impurity region layers 3a and 3b. Subsequently, for example with the condition of acceleration energy of 10 keV and dose of 4×10¹³/cm², ion implantation of B is performed from the direction perpendicular to the surface of substrate 1 to form p type impurity layers 2a and 2b so as to cover covering n type impurity region layers 3a and 3b, respectively.

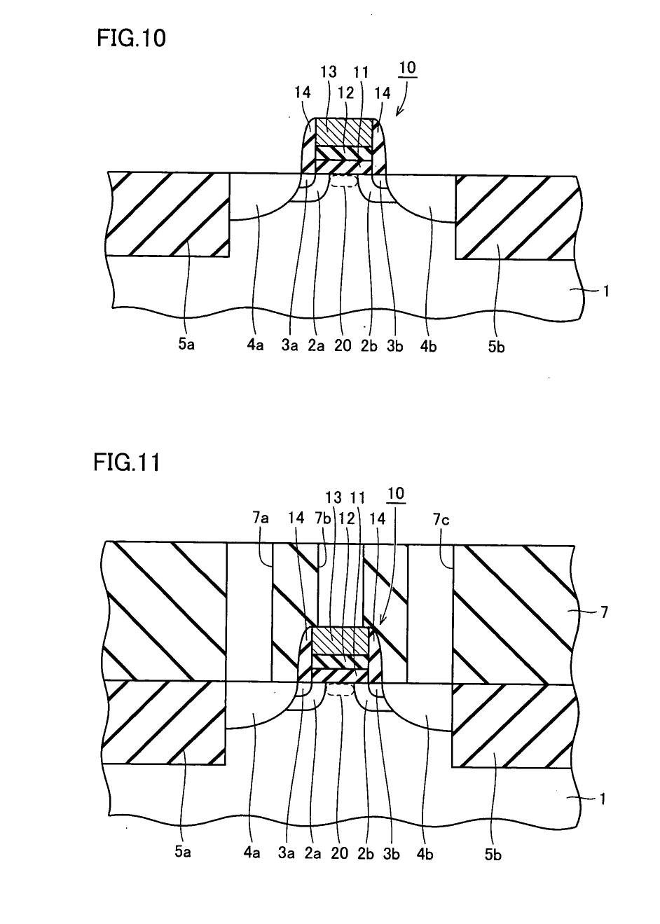

Next, referring to FIG. 10, for example using plasma assisted deposition method and at a temperature of 400° C., SiO₂ of 50 nm thickness is formed on substrate 1 so as to cover insulating films 11 and 12 and gate electrode 13. Then, through anisotropic dry etching, SiO₂ is selectively left on the sidewall portions of gate electrode 13, to form sidewalls 14. Next, using sidewalls 14 as a mask, for example with the condition of acceleration energy of 30 keV and dose of 2×10¹⁵/cm², ion implantation of As is performed from the direction perpendicular to the surface of substrate 1, to form n⁺ impurity regions 4a and 4b. Thereafter, substrate 1 is annealed for example in an atmosphere of nitride at a temperature of 1000° C. for five seconds, to activate the implanted ions. Thus, MISFET 10 is completed.

Next, referring to FIG. 11, on substrate 1, an interlayer insulating film 7 made of, for example TEOS (Tetra Ethyl Ortho Silicate), SiO₂, SiOC or the like is formed so as to cover MISFET 10. Subsequently, through normal photolithography and etching technique, holes 7a-7c reaching n⁺ impurity region 4a, gate electrode 13 and n⁺ type impurity region 4b, respectively, are formed in interlayer insulating film 7.

Next, referring to FIG. 1, a conductive film made of, for example, W, Al (aluminum), Cu (copper) or the like is formed on interlayer insulating film 7 so that holes 7a-7c are filled. Next, redundant conductive film on interlayer insulating film 7 is removed and contacts 8a-8c are formed. Subsequently, interconnection lines 9a-9c electrically connecting to contacts 8a-8c, respectively, are patterned on interlayer insulating film 7. Through the above-described processes, the semiconductor device in the present embodiment is completed.

In the semiconductor device in the present embodiment and the manufacturing method thereof, impurity concentration C of channel region 20 is set so that the maximum value of the mobility of electrons in channel region 20 of MISFET 10 is higher than the maximum value of the mobility of electrons in channel region 120 of MISFET 110. While the impurity concentration in a channel region has conventionally been about 5×10¹⁶/cm³, impurity concentration C of the present invention is higher than that, namely, at least 2×10¹⁷/cm³ and at most 1×10²⁰/cm³, for example. Thus, the mobility of electrons can be improved.

Additionally, by forming insulating film 11, insulating film 12 made of HfSiON that is a high-dielectric material can be separated from substrate 1. Thus, fixed charges in insulating film 12 can be separated from the channel region. As a result, the mobility of electrons can be improved.

By improving the mobility of electrons, the current passing between source and drain increases, and thus power consumption can be reduced. Further, fast operation can be realized.

According to the semiconductor device in the present embodiment, when the field intensity of channel region 20 is in a high field region, the mobility of electrons can be improved to a degree exceeding the universal curve.

The semiconductor device of the present invention further includes gate electrode 13 that contains polysilicon and that is formed on insulating film 12.

As compared with a conventional semiconductor device wherein a gate electrode made of polysilicon is formed on a gate insulating film made only of SiON, a semiconductor device wherein a gate electrode made of polysilicon is formed on a gate insulating film made of high-dielectric material attains the same threshold value with a lower impurity concentration of the channel region (this phenomenon is referred to as “pinning”.) Thus, if the impurity concentration of the channel region is set to be lower than the conventional impurity concentration with a semiconductor device wherein a gate electrode made of polysilicon is formed on a gate insulating film made of a high-dielectric material, a threshold value that is high enough for practical use can be obtained. As a result, applying the same power supply voltage for comparison, the effective field of HfSiON is lower than that of SiON. Accordingly, a semiconductor device capable of improving the mobility and having the threshold value that is high enough for practical use can be obtained.

In the manufacturing method in the present embodiment, substrate 1 is made of silicon, and insulating film 11a is formed by oxidizing the semiconductor substrate in an atmosphere containing oxygen at a temperature of at least 1000° C. and lower than 1100° C. at least 20 seconds and at most 40 seconds. Thus, insulating film 11 made of SiO₂ with an excellent film quality can be obtained. Additionally, performing heat treatment at a high temperature of at least 1000° C., Hf in insulating film 12a diffuses into insulating film 11a, whereby the mobility of electrons can be improved.

### Second Embodiment

The manufacturing method in the first embodiment showed formation of insulating film 11 made of SiO₂. In the present embodiment, a manufacturing method of forming insulating film 11 made of SiON in place of SiO₂ is described.

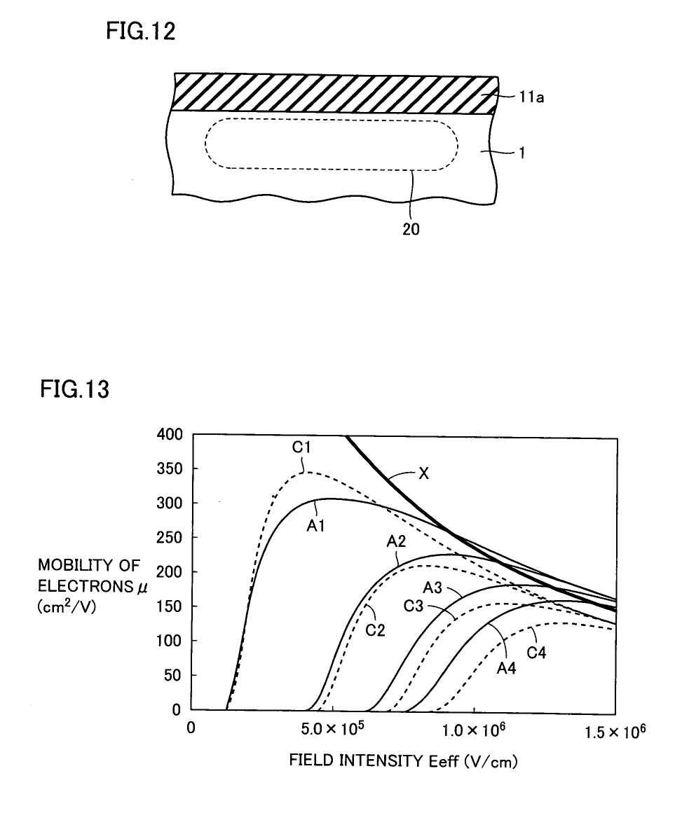

First, referring to FIG. 12, oxinitriding substrate 1 made of silicon in an N₂O atmosphere, insulating film 11a made of SiON is formed. Further, before oxinitriding in N₂O atmosphere, substrate 1 may be plasma-nitrided. Next, referring to FIG. 6, for example using MOCVD method, insulating film 12a made of HfSiO is formed.

The steps of the manufacturing method of a semiconductor device that follow are similar to those of the manufacturing method in the first embodiment shown in FIG. 1 and FIGS. 7-11. Accordingly, description thereof is not repeated.

In the manufacturing method of a semiconductor device in the present embodiment, substrate 1 is made of silicon and insulating film 11a is formed by oxinitriding substrate 1 in an N₂O atmosphere. Thus, insulating film 11 made of SiON with an excellent film quality can be obtained.

### EXAMPLE 1

In the present example, the semiconductor devices shown in FIG. 1 were manufactured with different combination of gate insulating film material and impurity concentration in the channel region, whereby specimens A1-A4 and specimens B1-B4 were obtained. Further, the semiconductor devices shown in FIG. 2 were manufactured with different impurity concentration in the channel region, whereby specimens C1-C4 were obtained. The gate insulating film material and the impurity concentration in the channel region for each of specimens A1-A4, B1-B4, and C1-C4 are as shown in the following Table 1.

TABLE 1

| | Gate insulating | | Impurity | |
|---|---|---|---|---|
| | film material | | concentration | |
| | Insulating | Insulating | in channel | |
| | film 12 | film 11 | region (/cm³) | Evaluation |
| Specimen A1 | HfSiON | SiO₂ | 3.0 × 10¹⁶ | Not the |
| | | | | product |
| | | | | of the |
| | | | | present |
| | | | | invention |
| Specimen A2 | | | 4.0 × 10¹⁷ | Product of |
| | | | | the present |
| | | | | invention |
| Specimen A3 | | | 9.0 × 10¹⁷ | Product of |
| | | | | the present |
| | | | | invention |
| Specimen A4 | | | 1.5 × 10¹⁸ | Product of |
| | | | | the present |
| | | | | invention |
| Specimen B1 | HfSiON | SiON | 3.0 × 10¹⁶ | Not the |
| | | | | product |
| | | | | of the |
| | | | | present |
| | | | | invention |
| Specimen B2 | | | 4.0 × 10¹⁷ | Product of |
| | | | | the present |
| | | | | invention |
| Specimen B3 | | | 9.0 × 10¹⁷ | Product of |
| | | | | the present |
| | | | | invention |
| Specimen B4 | | | 1.5 × 10¹⁸ | Product of |
| | | | | the present |
| | | | | invention |

| | | Impurity | |
|---|---|---|---|
| | | concentration | |
| | Gate insulating | in channel | |
| | film 111 material | region (/cm³) | Evaluation |
| Specimen C1 | SiON | 3.0 × 10¹⁶ | Not the product |
| Specimen C2 | | 4.0 × 10¹⁷ | of the present |
| Specimen C3 | | 9.0 × 10¹⁷ | invention |
| Specimen C4 | | 1.5 × 10¹⁸ | |

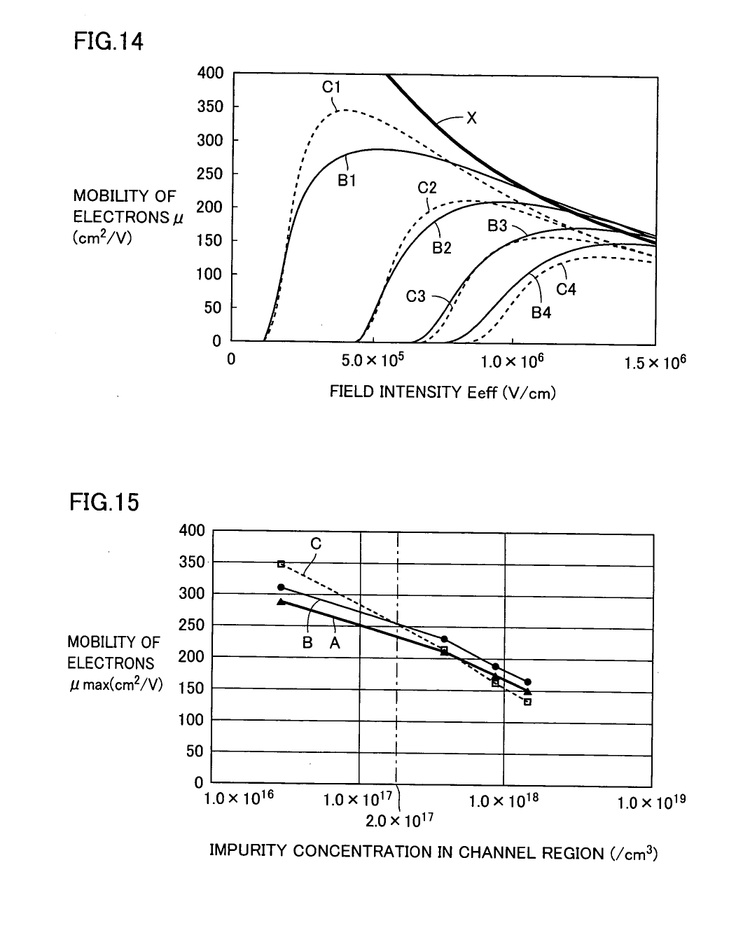

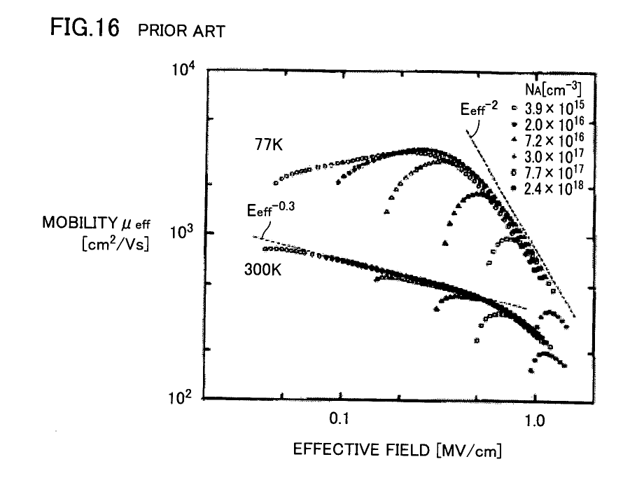

For each specimen A1-A4, B1-B4 and C1-C4 above, field intensity E_{eff} in the direction perpendicular to the semiconductor substrate surface in the channel region was changed to measure the mobility of electrons in the channel region. In FIGS. 13 and 14, line X is a universal curve. In FIG. 15, line A is a line connecting maximum values μₘₐₓ measured with each of specimen A1-A4, line B is a line connecting maximum values μₘₐₓ measured with specimen B1-B4, and line C is a line connecting maximum values μₘₐₓ measured with specimen C1-C4.

Referring to FIGS. 13-15, line A is greater than line C in the region where the impurity concentration of the channel region is at least 2.0×10¹⁷/cm³. Specifically, comparing specimens A1-A4 with specimens C1-C4 of the same impurity concentration, maximum values μₘₐₓ of the mobility of electrons of specimens A2-A4 are higher than that of specimens C2-C4, respectively.

Line B is greater than line C in the region where the impurity concentration of the channel region is at least 6.0×10¹⁷/cm³. Specifically, comparing specimens B1-B4 and specimens C1-C4 of the same impurity concentration, maximum values μₘₐₓ of the mobility of electrons of specimens B2-B4 are higher than that of specimens C2-C4, respectively.

In a high field region, each mobility μ of electrons in specimens A2-A4 and B2-B4 is greater than line X that is a universal curve. Thus, it can be seen that the mobility of electrons can be improved by specimens A2-A4 and B2-B4 which are the products of the present invention.

Applying the semiconductor device of the present invention to particularly a device of 65 nm nodes and beyond, a drastic improvement in the device characteristics such as on-current can be expected.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a semiconductor substrate having a channel region with an impurity concentration C;
a first gate insulating film containing silicon and oxygen and formed on said channel region; and
a second gate insulating film containing hafnium and oxygen and formed on said first gate insulating film, wherein
when there is a postulated semiconductor device including a postulated semiconductor substrate that has a postulated channel region with the impurity concentration C and that is made of a material identical to said semiconductor substrate and a postulated gate insulating film made solely of SiON and formed on said postulated channel region, the impurity concentration C of said channel region is set so that a maximum value of mobility of electrons in said channel region is higher than a maximum value of mobility of electrons in said postulated channel region.

2. The semiconductor device according to claim 1, wherein
said impurity concentration C is at least 2×10¹⁷/cm³ and at most 1×10²⁰/cm³.

3. The semiconductor device according to claim 1, wherein
said first gate insulating film is made of either SiON or SiO₂.

4. The semiconductor device according to claim 1, wherein
said second gate insulating film is made of HfSiON.

5. The semiconductor device according to claim 1, wherein
when a field intensity of said channel region is in a high field region, the mobility of electrons in said channel region exceeds a universal curve.

6. The semiconductor device according to claim 1, wherein
equivalent oxide thickness of said first gate insulating film is at least 0.5 nm and at most 1.0 nm.

7. The semiconductor device according to claim 1, further comprising
a gate electrode containing polysilicon and formed on said second gate insulating film.

8. A manufacturing method of a semiconductor device, comprising the steps of:
forming a channel region with an impurity concentration C in a semiconductor substrate;
forming a first gate insulating film containing silicon and oxygen on said channel region; and
forming a second gate insulating film containing hafnium and oxygen on said first gate insulating film, wherein
said impurity concentration C is set so that, in said step of forming a channel region, mobility of electrons in said channel region is higher than mobility of electrons in a channel region where only a gate insulating film made of silicon oxynitride is formed on the channel region with the impurity concentration C.

9. The manufacturing method of a semiconductor device according to claim 8, wherein
said semiconductor substrate is made of silicon, and
said first gate insulating film is formed by oxidizing said semiconductor substrate in an atmosphere containing oxygen at a temperature of at least 1000° C. and lower than 1100° C. for at least 20 seconds and at most 40 seconds.

10. The manufacturing method of a semiconductor device according to claim 8, wherein
said semiconductor substrate is made of silicon, and
said first gate insulating film is formed by oxinitriding said semiconductor substrate in an N₂O atmosphere.
